(19) United States
(12) Patent Application Publication
(10) Pub. No.: US 2024/0290404 A1
(43) Pub. Date: Aug. 29, 2024

(54) GATE VOLTAGE STEP AND PROGRAM VERIFY LEVEL ADJUSTMENT IN A MEMORY DEVICE

(71) Applicant: Micron Technology, Inc., Boise, ID (US)

(72) Inventors: Christina Papagianni, San Jose, CA (US); Murong Lang, San Jose, CA (US); Zhenming Zhou, San Jose, CA (US)

(21) Appl. No.: 18/423,992

(22) Filed: Jan. 26, 2024

Related U.S. Application Data
(60) Provisional application No. 63/486,851, filed on Feb. 24, 2023.

(51) Int. Cl. G11C 16/34; G11C 16/04; G11C 16/10

(52) U.S. Cl. CPC G11C 16/3459; G11C 16/0483; G11C 16/10; G11C 16/3495

(57) ABSTRACT

A request to perform a program operation on a memory cell of a memory device is received. A number of program erase cycles (PECs) associated with the memory device is determined. A temperature of the memory device is determined. A gate voltage step adjustment value and a program verify level adjustment value is determined based on the temperature and the number of PECs. A default gate voltage step is adjusted based the gate voltage step adjustment value. A default program verify level is adjusted based the program verify level adjustment value.

### RELATED APPLICATIONS

This application claims the benefit of U.S. Provisional Patent Application No. 63/486,851, filed Feb. 24, 2023, entitled “GATE VOLTAGE STEP AND PROGRAM VERIFY LEVEL ADJUSTMENT IN A MEMORY DEVICE,” which is incorporated by reference herein.

### TECHNICAL FIELD

Embodiments of the disclosure relate generally to memory sub-systems, and more specifically, relate to gate voltage step and program verify level adjustment in a memory device.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 illustrates an example of a table storing a gate voltage step adjustment value and a program verify level adjustment value for each temperature and program/erase cycle combination for use in adjusting a gate voltage step and a program verify level, in accordance with some embodiments of the present disclosure.

FIG. 3 illustrates a flow diagram of an example method of adjusting a gate voltage step and program verify level in a memory device, in accordance with some embodiments of the present disclosure.

FIG. 4 is a block diagram of an example computer system in which embodiments of the present disclosure may operate.

### DETAILED DESCRIPTION

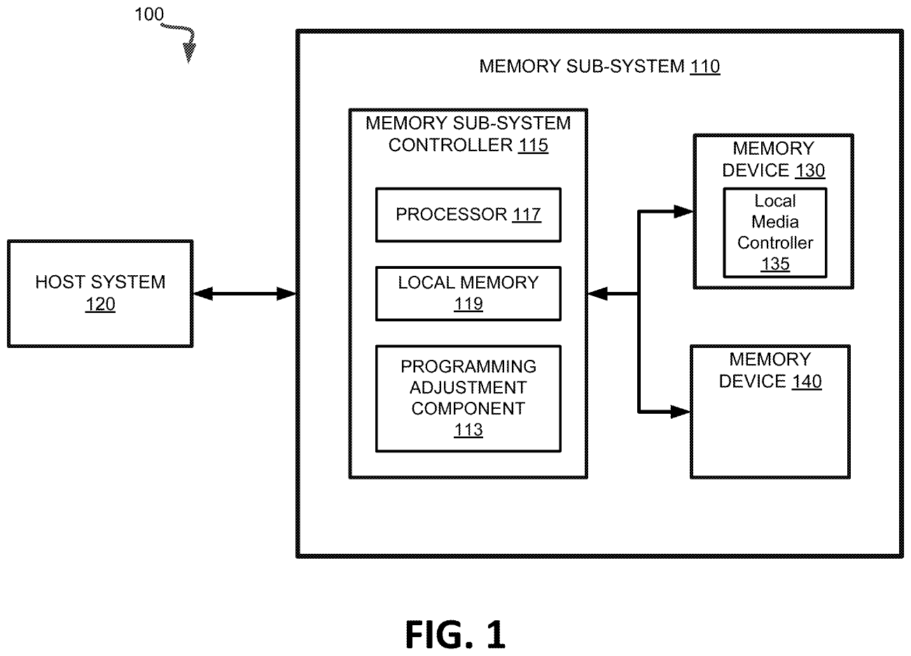

Aspects of the present disclosure are directed to adjusting a gate voltage step and program verify level in a memory device of a memory sub-system. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can includes of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

During a programming operation, selected memory cells can be programmed with the application of a programming voltage to a selected wordline. In some cases, an incremental step pulse programming process can be employed to maintain a tight cell threshold voltage distribution for higher data reliability. In the incremental step pulse programming process, a series of high-amplitude pulses of voltage levels having an increasing magnitude (e.g., each pulse is increased by a predefined pulse step height or programming gate voltage step) are applied to wordlines to which one or more memory cells are connected to gradually raise the voltage level of the memory cells to above a wordline voltage level corresponding to the programming operation (e.g., a desired programming level). The application of the uniformly increasing pulses by a wordline driver of the memory device enables the selected wordline to be ramped or increased to a wordline voltage level corresponding to the programming operation. Similarly, a series of voltage pulses having a uniformly increasing voltage level can be applied to the wordline to ramp the wordline to the corresponding wordline voltage level during other memory access operations (e.g., an erase operation).

The series of incrementing voltage programming pulses is applied to the selected wordline to increase a charge level, and thereby a threshold voltage, of each memory cell connected to or associated with that wordline. After each programming pulse, or after a number of programming pulses, a program verify operation is performed to determine if the threshold voltage of the one or more memory cells has increased to a desired programming level. For example, the pulses can be incrementally increased in value (e.g., by a programming gate voltage step (i.e., voltage value) such as 0.33V) to increase a charge stored on a charge storage structure corresponding to each pulse. The memory device can reach a target programming level voltage for a particular programming level by incrementally storing or increasing amounts of charge corresponding to the programming gate voltage step.

According to this approach, the series of programming pulses and program verify operations are applied to program each programming level (e.g., programming levels L1 to L7 for a TLC memory cell) in sequence. For example, this approach sequentially programs the levels of the memory cell (e.g., L1 to L7) by applying a first set of pulses to program level L1 to a first target voltage level, followed by the application of a second set of pulses to program level L2 to a second target voltage level, and so on until all of the levels are programmed.

Under certain circumstances, the memory device can be operated in an environment with varying temperatures (e.g., between-40 to 117 degrees Celsius). Temperature variations over time, such as a period of time between when data is written to a memory cell and when data is read from the memory cell, can impact the voltages stored in and read from the memory cell. (e.g., causing a threshold voltage shift). This change in temperature between when the data is written and when the data is read from a memory cell can be referred to as the cross temperature. Cross temperature conditions occur when the memory cell is programmed at a hot temperature and read at a cold temperature or when the memory cell is programmed at a cold temperature and read at a hot temperature. Depending on how the threshold voltage ranges (i.e., levels) are defined in the memory cell, the apparent read voltage may reflect a different data value. This shift can result in an increased raw bit error rate (RBER), which can be beyond the error correction capability of the underlying error correction code (ECC) and can be worsened as the memory device encounters program erase cycles (PECs). Accordingly, the larger the cross temperature and the more PECs the higher the RBER which is more likely beyond the error correction capability of the underlying ECC.

Aspects of the present disclosure address the above and other deficiencies by adjusting a gate voltage step and program verify level during a programming operation to lower RBER to avoid ECC and/or exceed the error correction capability of the underlying ECC. In one embodiment, the memory sub-system receives a request to perform a program operation on a memory cell of the memory device. The memory sub-system determines a current temperature (or temperature) of the memory device. The memory sub-system determines a number of program erase cycles (PECs) of the memory device. Based on the temperature and the number of PECs of the memory device, the memory sub-system determines a gate voltage step adjustment value to adjust a default gate voltage step and a program verify level adjustment value to adjust the default program verify level. In particular, the memory sub-system may obtain, from a programming adjustment data structure, the gate voltage step adjustment value and the program verifying level adjustment value.

The programming adjustment data structure may include a plurality of entries. Each entry of the programming adjustment data structure is identified by a programming temperature of the memory device at the number of PECs and includes a gate voltage step adjustment value and a program verifying level adjustment value. Each program verify level adjustment value at a respective temperature and a respective number of PECs is used to adjust the default program verify level during a program verify phase of the program operation on the memory cell to compensate for the shift in threshold voltage distribution that occurs due to extreme cross temperature. Each gate voltage step adjustment value at a respective temperature and a respective number of PECs is used to adjust the default gate voltage step during a programming phase of the program operation on the memory cell to compensate for the widening of threshold voltage distribution that occurs due to the number of PECs. Accordingly, the memory sub-system performs the read operation using the adjusted gate voltage step and the adjusted program verify level.

Advantages of the present disclosure include, but are not limited to, improving memory device performance, reliability, and quality of service of the memory device. More specifically, by adjusting the gate voltage step during programming threshold voltage distribution shifts that occur due to extreme cross temperature conditions of the memory sub-system may be mitigated. In addition to adjusting the gate voltage step during programming, adjusting the program verify level during programming may mitigate the effects the program erase cycles of the memory sub-system has on the threshold voltage distribution shifts. Accordingly, adjusting both the gate voltage step and the program verify level during program may improve reliability by reducing the need to initiate error handling which improves reliability and prevent the likelihood of exceeding the error correction capability of the underlying error correction code (ECC).

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCle bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously crased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically crasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a programming adjustment component 113 that can adjust a default program verify level and gate voltage step responsive based on a temperature and number of PECs of the memory device. In some embodiments, the memory sub-system controller 115 includes at least a portion of the programming adjustment component 113. In some embodiments, the programming adjustment component 113 is part of the host system 120, an application, or an operating system. In other embodiments, local media controller 135 includes at least a portion of programming adjustment component 113 and is configured to perform the functionality described herein.

The programming adjustment component 113 receives a request to perform a program operation on a memory cell of a memory device. Responsive to receiving the request, the programming adjustment component 113 determines a current temperature (or operating temperature) of memory device 130 and/or 140. The programming adjustment component 113 further determines a number of program erase cycles (PECs) of memory device 130 and/or 140.

Once the current temperature and the number of PECs of the memory device 130 and/or 140 is determined, the programming adjustment component 113 may retrieve, from a programming adjustment data structure (or table), a gate voltage step adjustment value to adjust a default gate voltage step and a program verify level adjustment value to adjust a default program verify level for the requested program operation. The programming adjustment table includes a plurality of entries. Each entry of the plurality of entries is identified by a temperature (or temperature range) and a number of PECs (or range of PECs). Each entry identified by the temperature and the number of PECs provides a gate voltage step adjustment value used to adjust a default gate voltage step and a program verify level adjustment value used to adjust a default program verify level when the memory device is at the temperature and has experienced the number of PECs.

Accordingly, the gate voltage step adjustment value and the program verify level adjustment value is received from the programming adjustment by querying the programming adjustment table using the current temperature and the number of PECs. In particular, the programming adjustment component 113 determines whether the current temperature and the number of PECs match an entry of the plurality of entries of the programming adjustment table. If the current temperature match (or falls within range) of a temperature (or temperature range) and the number of PECs match (or falls within range) of a number of PECs (or range of PECs) associated with an entry of the plurality of entries of the programming adjustment table, the programming adjustment component 113 selects the corresponding gate voltage step adjustment value and program verify level adjustment value.

The programming adjustment component 113 adjusts, using the gate voltage step adjustment value and the program verify level adjustment value, the default gate voltage adjustment, and the default program verify level. In particular, the programming adjustment component 113 adds the gate voltage step adjustment value to the default gate voltage step adjustment and the program verify level adjustment value to the default program verify level.

Thus, the adjusted gate voltage step and the adjusted program verify level may be used in the program operation. For example, during the programming phase of the program operation, a series of pulses of voltage levels, gradually increased by the adjusted gate voltage step, are applied to wordlines to which a memory cell to be programmed is connected to gradually raise the voltage level of the memory cell to above a wordline voltage level corresponding to the programming operation (e.g., a desired programming level). After each pulse, or after a number of pulses, a program verify operation (e.g., program verify phase of the program operation) is performed to determine if the threshold voltage of the memory cell has increased to the adjusted program verify level (e.g., a desired programming level).

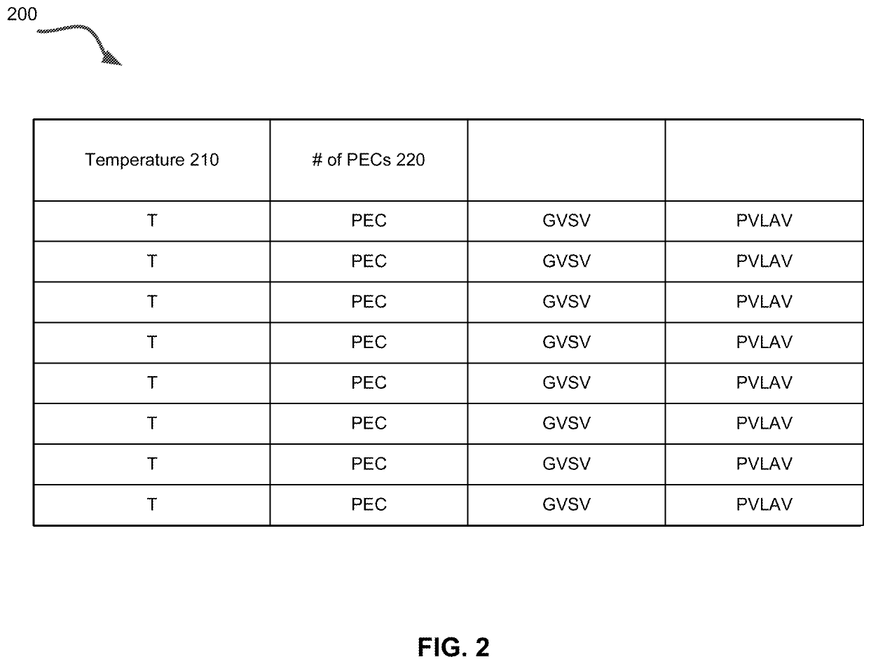

FIG. 2 illustrates an example of a programming adjustment data structure (e.g., table) 200 that provides program verify level adjustment values used to adjust a default program verify level and gate voltage step adjustment values to adjust a default gate voltage step, in accordance with some embodiments of the present disclosure. In one embodiment, the programming adjustment data structure 200 is stored in the local memory (e.g., local memory 119 of FIG. 1). The programming adjustment data structure 200 includes a plurality of entries identified by a temperature (or temperature range) 210 and a number of PECs (or range of PECs) 220. Each entry includes a gate voltage step adjustment value (e.g., GVSV) and a program verifying level adjustment value (e.g., PVLAV). Each entry provides the gate voltage step adjustment value (e.g., GVSV) and the program verifying level adjustment value (e.g., PVLAV) necessary to adjust the default gate voltage step and the default program verify level used during a program operation to prevent higher errors of the memory cell during extreme cross temperature conditions at various PECs of the memory device.

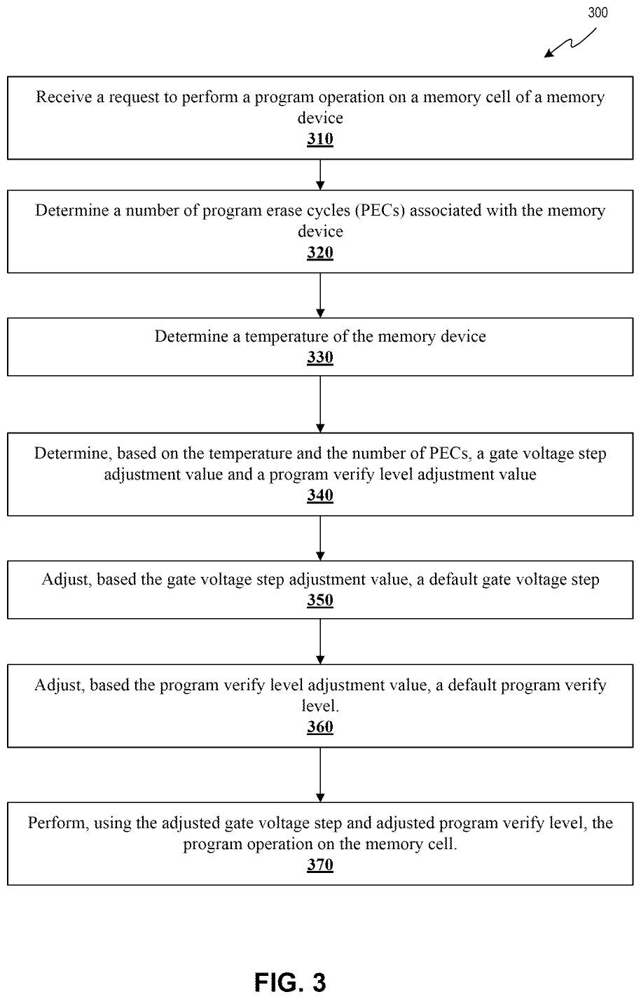

FIG. 3 is a flow diagram of an example method 300 of adjusting the default program verify level and a default gate voltage step during a program operation, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the programming adjustment component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 310, the processing logic receives a, from a host system, request to perform a program operation on a memory cell of a memory device. At operation 320, the processing logic determines a number of program crase cycles (PECs) associated with the memory device. As previously described, each PEC represents a program erase cycle encountered by the memory device. Accordingly, the number of PECs refers to a total count of all PECs encountered by the memory device. Thus, to determine the number of PECs associated with the memory device, the processing logic counts each PEC encountered by the memory device. In some embodiments, the count is maintained by the memory sub-system controller and can be retrieved by the processing logic.

At operation 330, the processing logic determines a temperature of the memory device. The processing logic determines the temperature of the memory device by obtaining from the memory sub-system controller a current temperature of the memory device.

At operation 340, the processing logic determines, based on the temperature and the number of PECs, a gate voltage step adjustment value and a program verify level adjustment value. The processing logic determines the gate voltage step adjustment value and the program verify level adjustment value by identifying, from a plurality of entries in a programming adjustment data structure, an entry in which the temperature satisfies a temperature criterion and the number of PECs satisfies a PEC criterion.

The entry includes a gate voltage step adjustment value and a program verify level adjustment. Each entry of the plurality of entries in the programming adjustment data structure is identified by satisfying a temperature criterion and a PEC criterion. The temperature criterion is satisfied if the temperature matches a temperature threshold (e.g., a predetermined temperature) or falls within a temperature threshold range (e.g., a predetermined temperature range) associated with a respective entry. The PEC criterion is satisfied if the number of PECs falls matches a PEC threshold (e.g., a predetermined number of PECs) or falls within a PEC threshold range (e.g., a predetermined range of PECs) associated with a respective entry. As previously described, each entry identified by the temperature and the number of PECs provides a gate voltage step adjustment value and a program verify level adjustment value used to adjust a default gate voltage step and a default program verify level when the memory device is at the temperature and has experienced the number of PECs.

At operation 350, the processing logic adjusts, based the gate voltage step adjustment value, a default gate voltage step. At operation 360, the processing logic adjusts, based the program verify level adjustment value, a default program verify level. As previously described, the default gate voltage is adjusted by adding the gate voltage step adjustment value to the default gate voltage step adjustment and the default program verify level is adjusted by adding the program verify level adjustment value to the default program verify level.

Depending on the embodiment, at operation 370, the processing logic performs, using the adjusted gate voltage step and adjusted program verify level, the program operation on the memory cell. In some embodiments, the processing logic performs the program operation by incrementally applying, from an initial voltage value to a final voltage value, the adjusted gate voltage step to a programming voltage during a programming phase of the program operation. In some embodiments, the processing logic determines whether a threshold voltage of the memory cell has increased to the final voltage value by comparing the threshold voltage to the adjusted program verify level during a program verify phase of the program operation.

In other words, as previously described, during the programming phase of the program operation, a series of pulses of voltage levels, gradually increased by the adjusted gate voltage step, are applied to wordlines to which a memory cell to be programmed is connected gradually raise the voltage level of the memory cell to above a wordline voltage level. During the program verify phase of the program operation, determine if the threshold voltage of the memory cell has increased to the adjusted program verify level (e.g., a desired programming level).

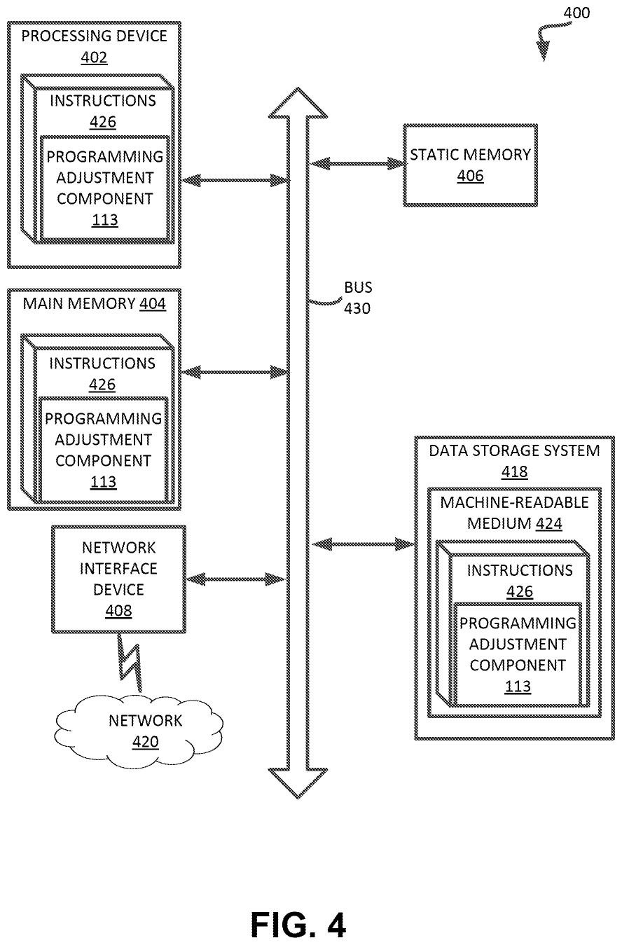

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the programming adjustment component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or RDRAM, etc.), a static memory 406 (e.g., flash memory, static random access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a programming adjustment component (e.g., the programming adjustment component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
receiving a request to perform a program operation on a memory cell of a memory device;
determining a number of program erase cycles (PECs) associated with the memory device;
determining a temperature of the memory device;
determining, based on the temperature and the number of PECs, a gate voltage step adjustment value and a program verify level adjustment value;
adjusting, based the gate voltage step adjustment value, a default gate voltage step; and
adjusting, based the program verify level adjustment value, a default program verify level.

2. The method of claim 1, further comprising:
performing, using the adjusted gate voltage step and adjusted program verify level, the program operation on the memory cell.

3. The method of claim 2, wherein performing, using the adjusted gate voltage step and adjusted program verify level, the program operation comprises:
incrementally applying, from an initial voltage value to a final voltage value, the adjusted gate voltage step to a programming voltage during a programming phase of the program operation; and
determining whether a threshold voltage of the memory cell has increased to the final voltage value by comparing the threshold voltage to the adjusted program verify level during a program verify phase of the program operation.

4. The method of claim 1, wherein determining, based on the temperature and the number of PECs, the gate voltage step adjustment value and the program verify level adjustment value further comprises:
identifying, from a plurality of entries in a programming adjustment data structure, an entry in which the temperature satisfies a temperature criterion and the number of PECs satisfies a PEC criterion, the entry comprising the gate voltage step adjustment value and the program verify level adjustment.

5. The method of claim 4, wherein each entry of the plurality of entries in the programming adjustment data structure is identified by satisfying a temperature criterion and a PEC criterion.

6. The method of claim 4, wherein the temperature criterion is satisfied if the temperature falls within a temperature threshold range associated with a respective entry.

7. The method of claim 4, wherein the PEC criterion is satisfied if the number of PECs falls within a PEC threshold range associated with a respective entry.

8. A system comprising:
a memory device; and
a processing device, operatively coupled to the memory device, the processing device to perform operations comprising:
receiving a request to perform a program operation on a memory cell of a memory device;
determining a number of program erase cycles (PECs) associated with the memory device;
determining a temperature of the memory device;
determining, based on the temperature and the number of PECs, a gate voltage step adjustment value and a program verify level adjustment value;
adjusting, based the gate voltage step adjustment value, a default gate voltage step; and
adjusting, based the program verify level adjustment value, a default program verify level.

9. The system of claim 8, wherein the processing device to perform operations further comprising:
performing, using the adjusted gate voltage step and adjusted program verify level, the program operation on the memory cell.

10. The system of claim 9, wherein performing, using the adjusted gate voltage step and adjusted program verify level, the program operation comprises:
incrementally applying, from an initial voltage value to a final voltage value, the adjusted gate voltage step to a programming voltage during a programming phase of the program operation; and
applying the adjusted program verify level during a program verify phase of the program operation.

11. The system of claim 8, wherein determining, based on the temperature and the number of PECs, the gate voltage step adjustment value and the program verify level adjustment value further comprises:
identifying, from a plurality of entries in a programming adjustment data structure, an entry in which the temperature satisfies a temperature criterion and the number of PECs satisfies a PEC criterion, the entry comprising the gate voltage step adjustment value and the program verify level adjustment.

12. The system of claim 11, wherein each entry of the plurality of entries in the programming adjustment data structure is identified by satisfying a temperature criterion and a PEC criterion.

13. The system of claim 11, wherein the temperature criterion is satisfied if the temperature falls within a temperature threshold range associated with a respective entry.

14. The system of claim 11, wherein the PEC criterion is satisfied if the number of PECs falls within a PEC threshold range associated with a respective entry.

15. A non-transitory computer readable storage medium including instructions that, when executed by a processing device, cause the processing device to perform a method comprising:
receiving a request to perform a program operation on a memory cell of a memory device;
determining a number of program erase cycles (PECs) associated with the memory device;
determining a temperature of the memory device;
determining, based on the temperature and the number of PECs, a gate voltage step adjustment value and a program verify level adjustment value;
adjusting, based the gate voltage step adjustment value, a default gate voltage step; and
adjusting, based the program verify level adjustment value, a default program verify level.

16. The non-transitory computer readable storage medium of claim 15, wherein causing the processing device to perform a method further comprising:
performing, using the adjusted gate voltage step and adjusted program verify level, the program operation on the memory cell.

17. The non-transitory computer readable storage medium of claim 15, wherein determining, based on the temperature and the number of PECs, the gate voltage step adjustment value and the program verify level adjustment value further comprises:
identifying, from a plurality of entries in a programming adjustment data structure, an entry in which the temperature satisfies a temperature criterion and the number of PECs satisfies a PEC criterion, the entry comprising the gate voltage step adjustment value and the program verify level adjustment.

18. The non-transitory computer readable storage medium of claim 17, wherein each entry of the plurality of entries in the programming adjustment data structure is identified by satisfying a temperature criterion and a PEC criterion.

19. The non-transitory computer readable storage medium of claim 18, wherein the temperature criterion is satisfied if the temperature falls within a temperature threshold range associated with a respective entry.

20. The non-transitory computer readable storage medium of claim 18, wherein the PEC criterion is satisfied if the number of PECs falls within a PEC threshold range associated with a respective entry.
